(19) United States
(12) Patent Application Publication
(10) Pub. No.: US 2024/0353353 A1
(43) Pub. Date: Oct. 24, 2024

(54) MULTI-LAYER HIGH-ASPECT RATIO X-RAY GRATING AND METHOD OF MANUFACTURE

(71) Applicants: Karim S. KARIM, Waterloo (CA); Abdollah PIL-ALI, Waterloo (CA)

(72) Inventors: Karim S. KARIM, Waterloo (CA); Abdollah PIL-ALI, Waterloo (CA)

(21) Appl. No.: 18/682,988

(22) PCT Filed: Aug. 17, 2022
(86) PCT No.: PCT/CA2022/051247

§ 371 Date: Feb. 12, 2024

Related U.S. Application Data
(60) Provisional application No. 63/233,880, filed on Aug. 17, 2021.

(51) Int. Cl. G01N 23/041; G03F 7/00; G03F 7/20; G03F 9/00; G21K 1/06

(52) U.S. Cl. CPC G01N 23/041; G03F 7/0035; G03F 7/2022; G03F 9/7003; G21K 1/062

(57) ABSTRACT

The disclosure is directed at a multi-layer, high-aspect ratio X-ray grating apparatus and method of fabrication. In one embodiment, the disclosure may include a self-alignment methodology, or process, combined with a multiple layer structure fabrication. The grating may include a substrate with a seed layer on top. The grating further includes at least one patterned non-X-ray absorbing layer and at least one X-ray absorbing layer atop the seed layer.

### CROSS-REFERENCE TO OTHER APPLICATIONS

The current disclosure claims priority from U.S. Provisional Application No. 63/233,880 filed Aug. 17, 2021, which is hereby incorporated by reference.

### FIELD

The current disclosure is generally directed at X-ray phase contrast imaging and, more specifically, at a multi-layer high-aspect ratio X-ray grating and method of fabrication.

### BACKGROUND

X-ray phase-contrast is a method of imaging that has extended the practicality of the use of X-rays in visualizing soft as well as hard tissues. Applications enabled by X-ray phase-contrast imaging (XPCi) span across many fields, from industry and science to medicine and biology. These techniques, which rely on X-ray absorption masks or gratings, provide higher contrast and sensitivity compared to non-grating-based techniques. These grating-based XPCi techniques also produce multi-modal information—absorption (transmission), phase, and small angle scattering (dark field)—with single-shot imaging, which provide quantitative inputs for analyzing samples of interest. X-ray absorption grating utilizes high aspect-ratio X-ray absorber structures to translate incoming X-rays into individual beamlets. These absorption gratings are one of the imaging system components that define the quality of imaging. Therefore, any imperfection in their fabrication directly affects the final image quality, leading to image artifacts or loss of image quality and detail information.

For high-resolution imaging employing high-resolution detectors, absorption grating fabrication becomes challenging since the gratings require periodic structures with a high-aspect ratio in the micron-scale range to absorb X-ray photons and create fine beamlets. Fabrication of gratings for compact systems or higher energy imaging applications becomes even more problematic due to the stringent requirements on the grating feature sizes and their aspect ratio. Moreover, the need for a larger field-of-view (FOV) is on the rise with the development and/or use of XPCi methods. Applications, such as clinical diagnostic and whole-body imaging as well as industrial and security inspections, requiring a larger FOV also require large area absorption gratings.

Therefore, there is provided a novel multi-layer high-aspect ratio X-ray grating and method of fabrication.

### SUMMARY

The disclosure is directed at a multi-layer, high-aspect ratio X-ray grating apparatus and method of fabrication.

In one aspect of the disclosure, there is provided a method of fabricating a multi-layer X-ray grating including applying a seed layer on a radiation transparent substrate; fabricating at least one patterned non-X-ray absorbing layer atop the seed layer, the at least one patterned non-X-ray absorbing layer including gaps; and fabricating at least one X-ray absorbing layer atop the seed layer into the gaps of the at least one non-X-ray absorbing layer.

In another aspect, fabricating the at least one patterned non-X-ray absorbing layer includes exposing the grating to backside radiation exposure. In a further aspect, fabricating the at least one X-ray absorbing layer includes exposing the grating to backside radiation exposure. In yet another aspect, exposing the grating to backside radiation exposure enables self-alignment of the at least one patterned X-ray absorbing layer. In yet a further aspect, exposing the grating to backside radiation exposure enables self-alignment of the at least one X-ray absorbing layer.

In an aspect, the backside radiation exposure is performed via ultraviolet (UV) exposure, extreme UV (EUV) exposure, deep DUV (DUV) exposure, near infrared (NIR) exposure, infra-red (IR) exposure or X-ray lithography.

In another aspect of the disclosure, there is provided a multi-layer high-aspect ratio X-ray grating including a substrate; a seed layer on top of the substrate; at least one patterned non-X-ray absorbing layer atop the seed layer, the at least one patterned non-X-ray absorbing layer including gaps; and at least one X-ray absorbing layer atop the seed layer, the at least one X-ray absorbing layer located within the gaps of the at least one patterned non-X-ray absorbing layer.

In yet another aspect, the seed layer is at least one of opaque or electrically conductive. In another aspect, the at least one patterned non-X-ray absorbing layer is a photo-sensitive layer. In a further aspect, the at least one patterned non-X-ray absorbing layer is a layer of negative photoresist, a layer of positive photoresist, a layer of an epoxy-based polymer, a layer of a polymer, or a layer of photosensitive material. In yet a further aspect, the at least one X-ray absorbing layer is made from gold, platinum, nickel, lead, selenium, bismuth, tungsten, or indium. In another aspect, the grating further includes an adhesion layer atop the seed layer, where the adhesion layer may be MPTS.

In yet a further aspect of the disclosure, there is provided a phase contrast imaging system including an X-ray source; an X-ray detector; and at least one multi-layer high-aspect ratio X-ray grating including: a substrate; a seed layer on top of the substrate; at least one patterned non-X-ray absorbing layer atop the seed layer, the at least one patterned non-X-ray absorbing layer including gaps; and at least one X-ray absorbing layer atop the seed layer, the at least one X-ray absorbing layer located within the gaps of the at least one patterned non-X-ray absorbing layer; wherein the X-ray grating is located between the X-ray source and the X-ray detector; and wherein an object of interest is located between the X-ray source and the X-ray detector.

In yet another aspect, a first distance between the X-ray source and the object of interest and a second distance between the object of interest and the X-ray detector are selected based on X-ray source, X-ray detector and X-ray grating specifications. In another aspect, the at least one patterned non-X-ray absorbing layer is a photosensitive layer. In yet another aspect, the at least one X-ray absorbing layer is made from gold, platinum, nickel, lead, selenium, bismuth, tungsten, or indium. In a further aspect, the high-aspect ratio X-ray grating is fabricated using at least one of a backside exposure process or a self-alignment process.

### BRIEF DESCRIPTION OF THE DRAWINGS

Embodiments will now be described, by way of example only, with reference to the attached drawings, in which:

FIG. 1a is a front view of a multi-layer high-aspect ratio X-ray grating;

FIG. 1b is a front view of a seed layer of the X-ray grating of FIG. 1a

FIG. 2 is a flowchart outlining a method of multi-layer high-aspect ratio X-ray grating fabrication;

FIGS. 3a to 3h are a set schematic drawings showing one embodiment of the method of FIG. 2;

FIG. 4 is an enlarged view of FIG. 3b;

FIGS. 5a to 5l are a set of schematic drawings showing another method of multi-layer high-aspect ratio X-ray grating fabrication;

FIG. 5m is an image of a delaminated SU-8 film;

FIG. 5n is a schematic diagram of a mis-aligned multi-layer SU-8 film;

FIGS. 6a to 6c are images of alignment accuracy for various feature sizes of SU-8 structures;

FIGS. 7a to 7n are a set of schematic diagrams showing a further method of fabricating self-aligned multi-layer high-aspect ratio gratings;

FIGS. 70 to 7q are schematic drawings showing another embodiment of FIGS. 7b to 7e;

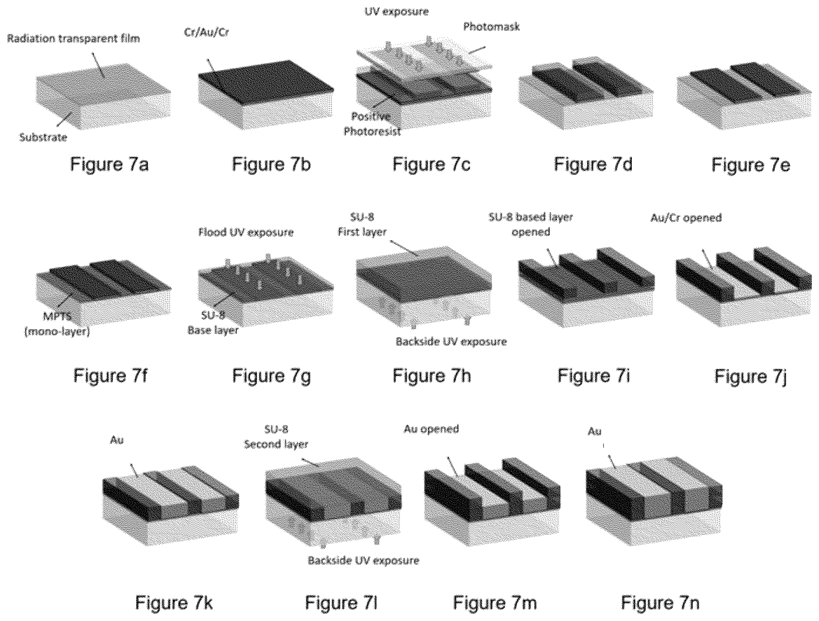

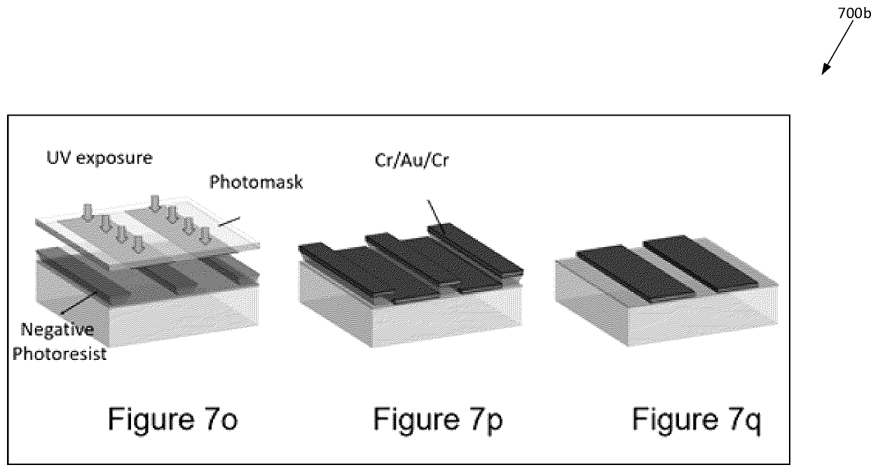

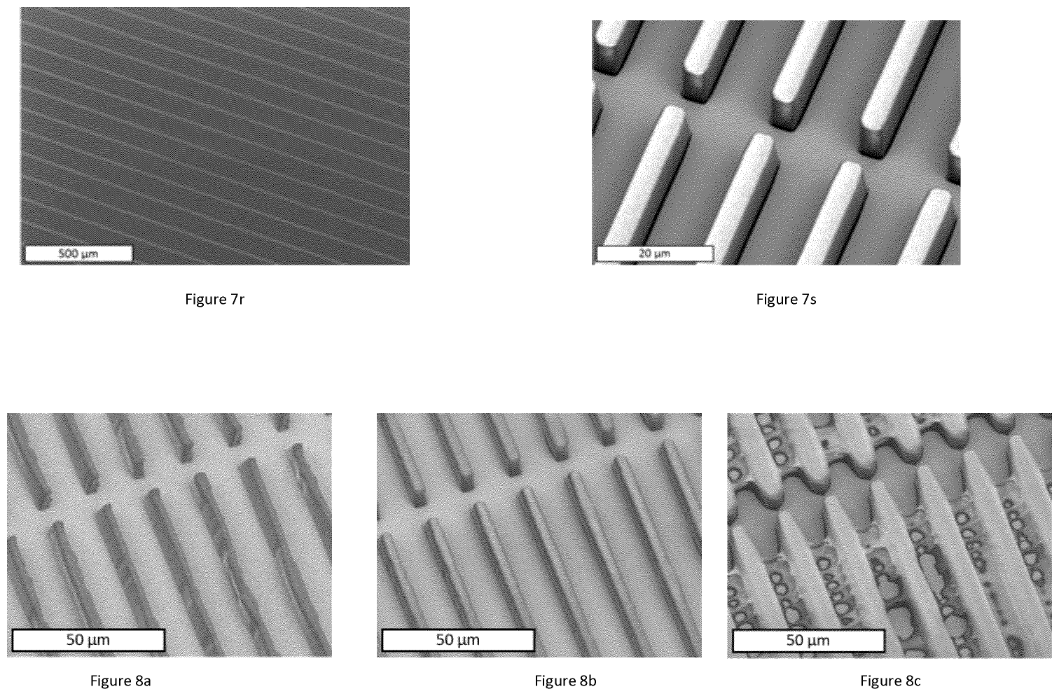

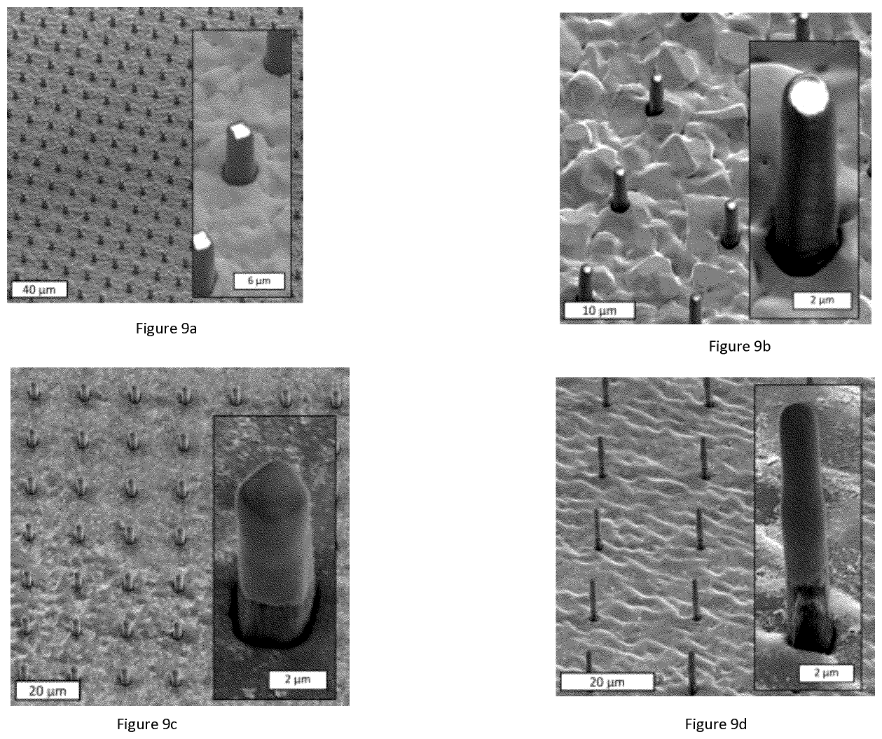

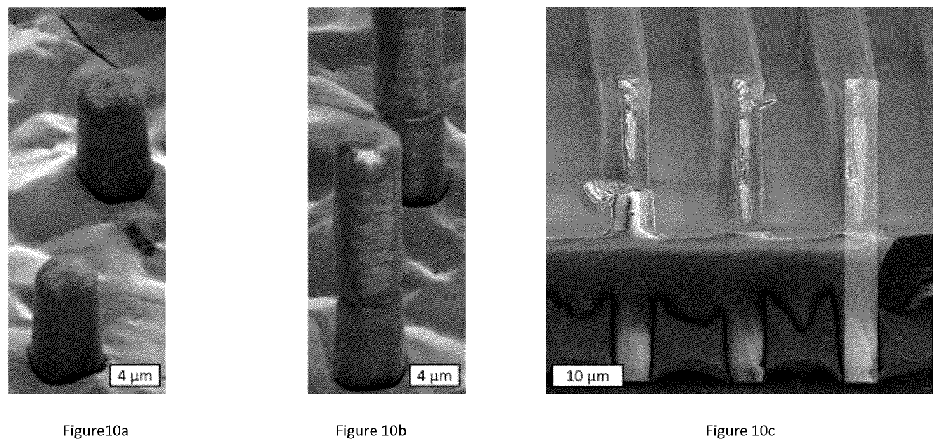

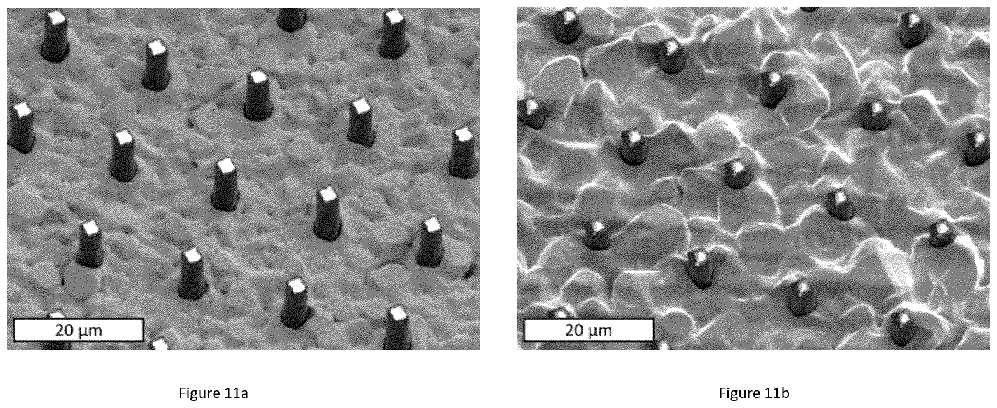

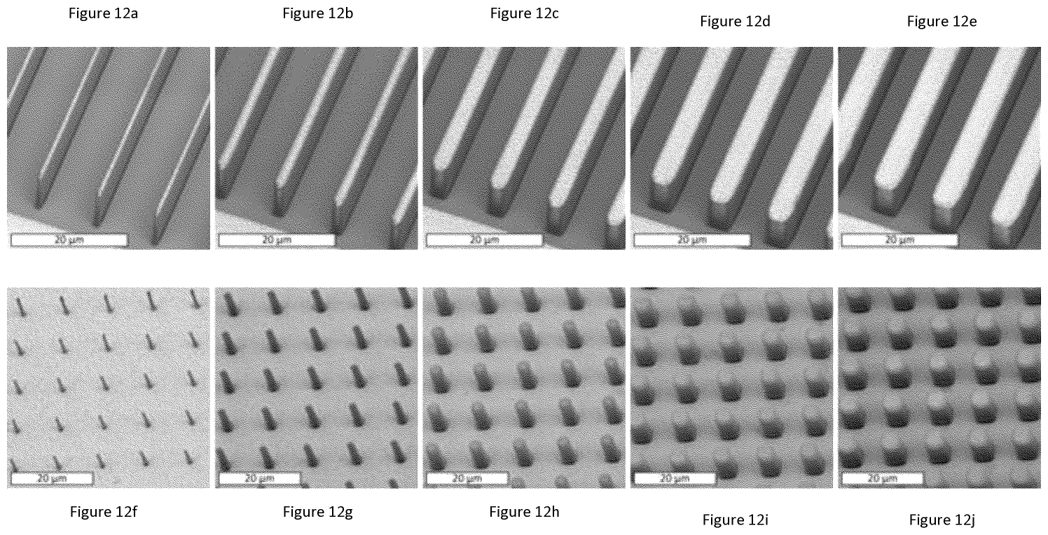

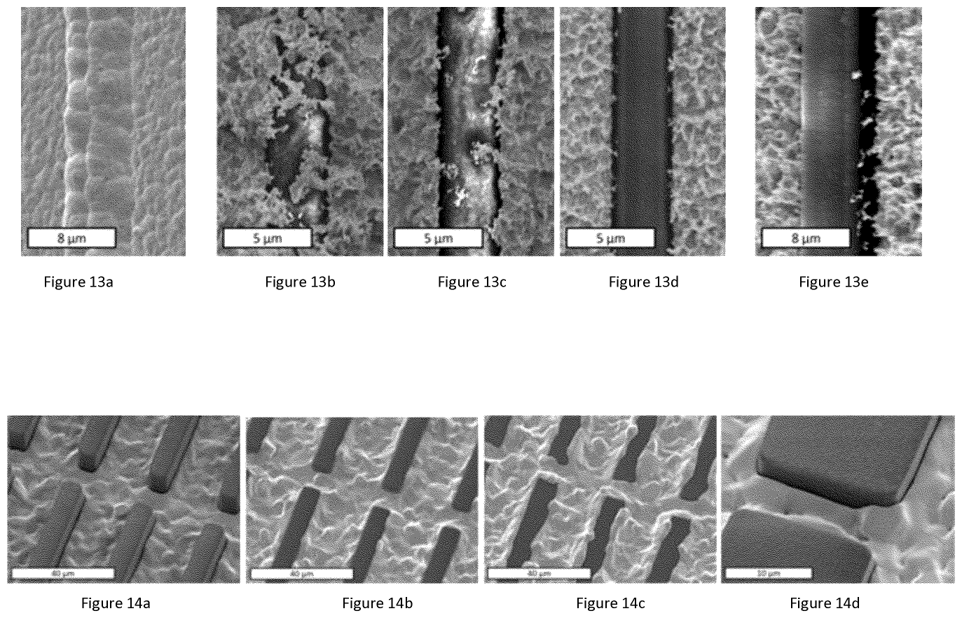

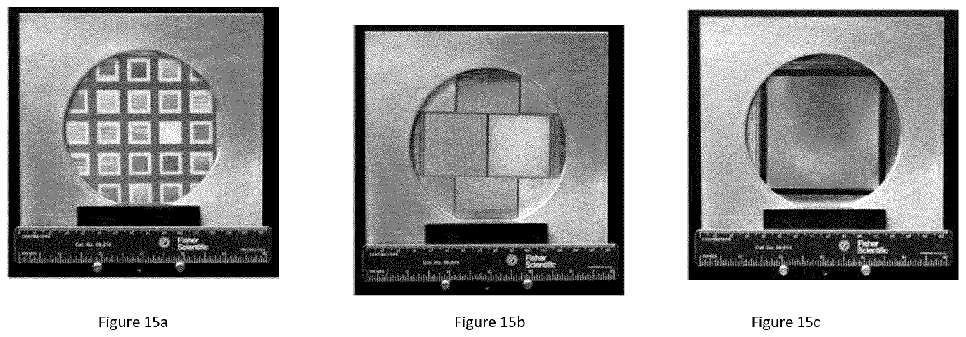

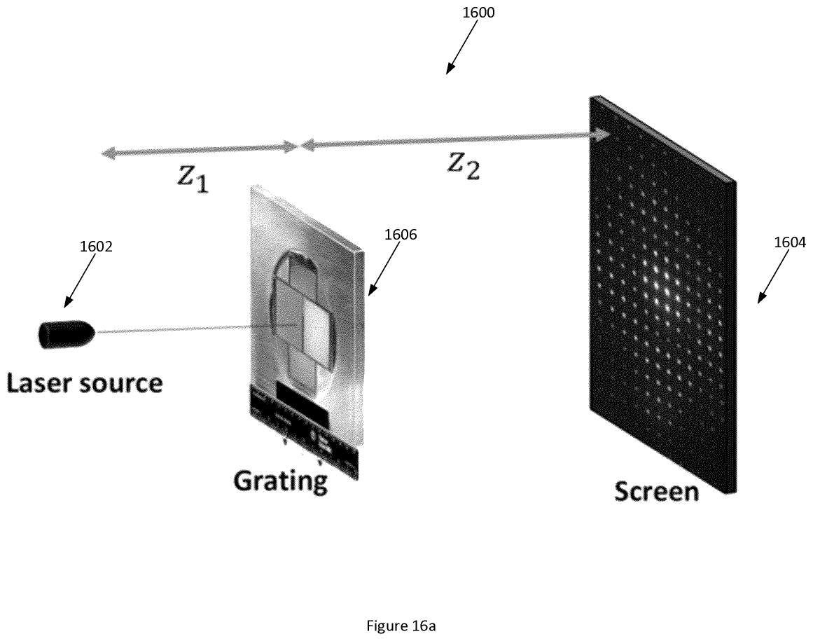

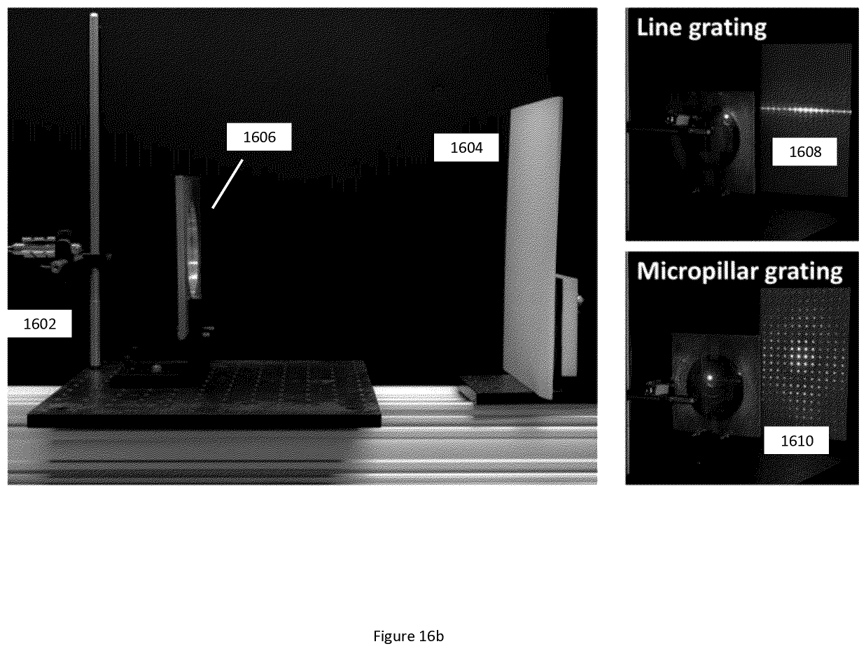

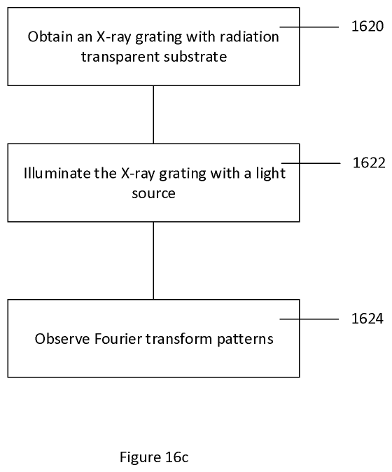

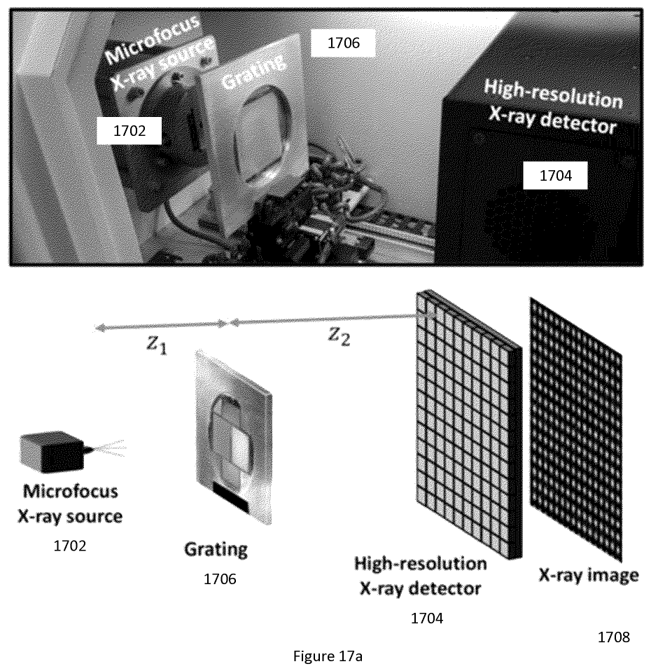

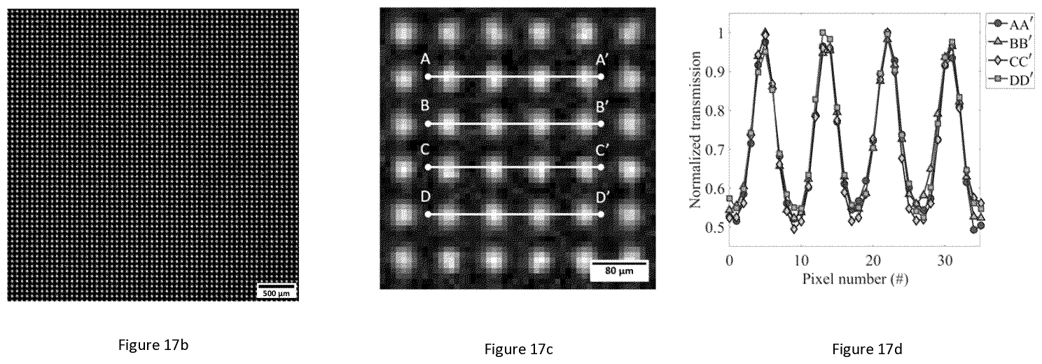

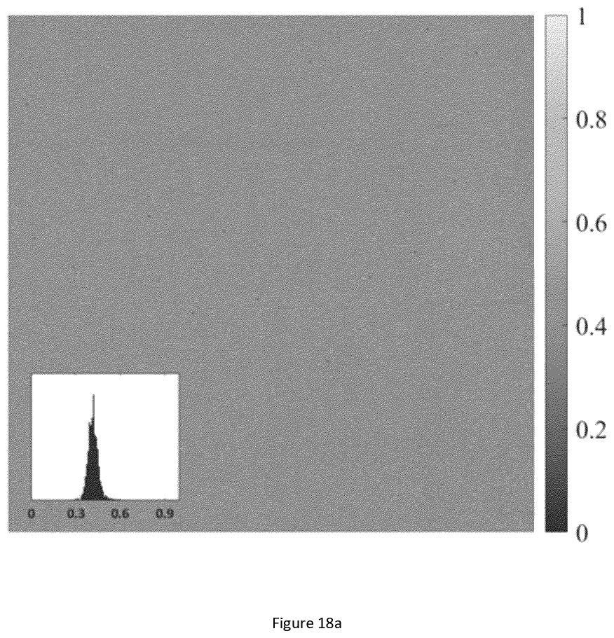

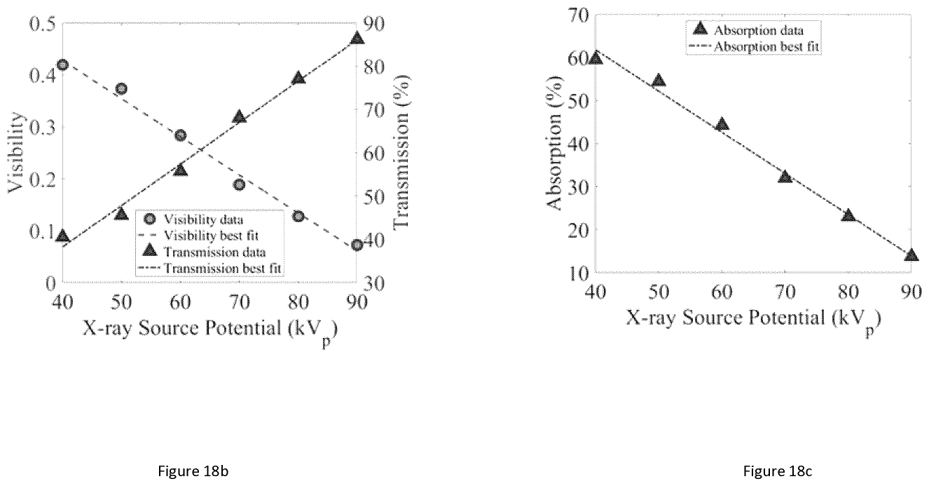

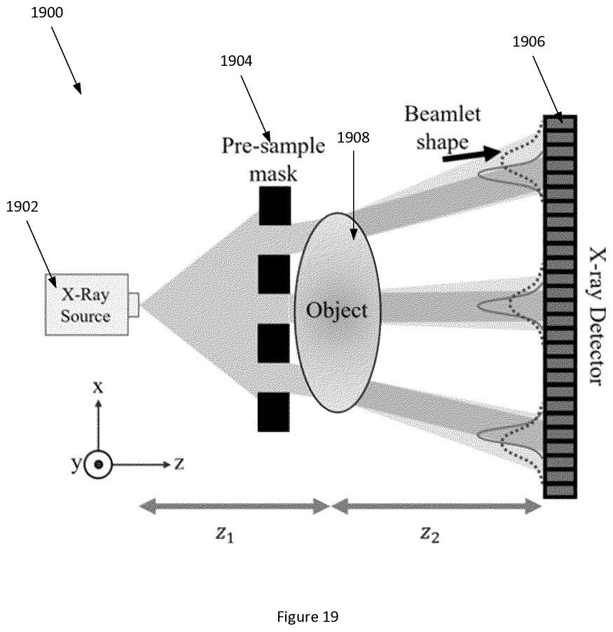

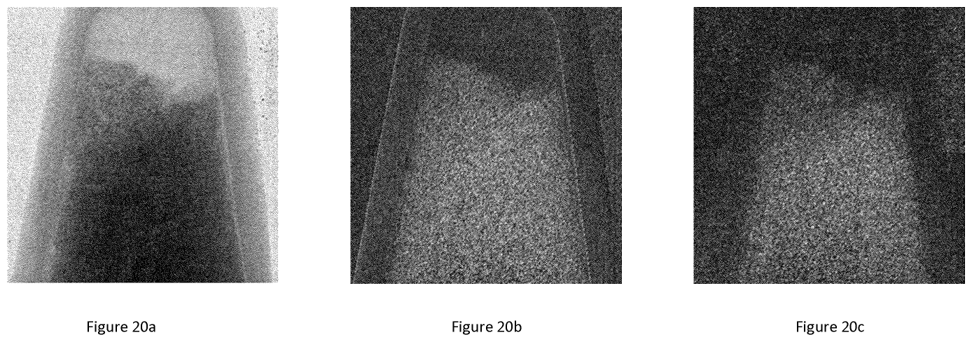

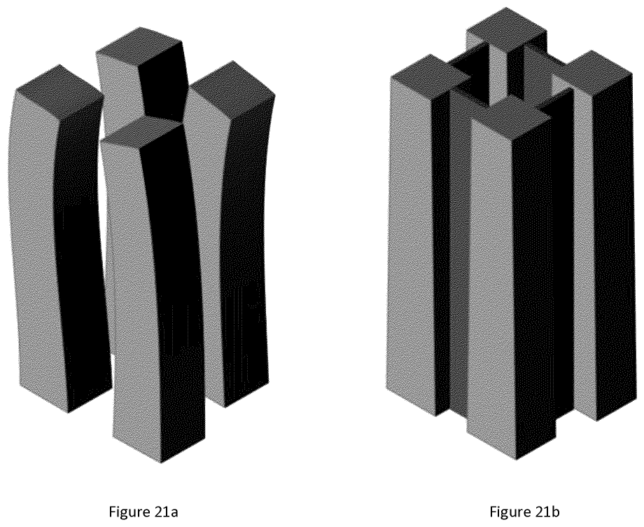

FIG. 7r is an SEM image of a pattern transfer over a large area;

FIG. 7s is an enlarged SEM image of the pattern transfer of FIG. 7r;

FIGS. 8a to 8c are SEM images showing the effect of exposure dose on the quality of pattern transfer in the self-aligned backside UV lithography;

FIGS. 9a to 9d are SEM images of the second SU-8 layer in various feature sizes of micropillar-based gratings;

FIGS. 10a to 10c are SEM images of micropillar and line gratings through the self-aligned multi-layer fabrication process;

FIGS. 11a and 11b are SEM images of micropillar-based grating with the second layer of SU-8 being electroplated;

FIGS. 12a to 12j are SEM images of pattern transfer of various feature sizes through self-aligned backside UV lithography;

FIGS. 13a to 13e are SEM images of gold electroplating;

FIGS. 14a to 14d are SEM images of indium electroplated samples;

FIGS. 15a to 15c are images of various sized fabricated gratings on 4-inch glass;

FIG. 16a is a schematic drawing of a test setup for investigating a quality of an X-ray grating;

FIG. 16b is a set of images of the test setup of FIG. 16a showing test patterns of micropillar and line gratings on a screen;

FIG. 16c is a flowchart outlining a method of testing a quality of an X-ray grating;

FIG. 17a is a schematic drawing of a test setup for investigating X-ray projection of an X-ray grating;

FIG. 17b is an image of an example X-ray projection of the grating registered with a detector;

FIG. 17c is an enlarged image of the X-ray projection of FIG. 17b;

FIG. 17d is a graph showing transmission profiles of cross-sectional lines of FIG. 17c;

FIG. 18a is an image showing a visibility map of an X-ray grating;

FIGS. 18b and 18c are graphs showing visibility, absorption, and transmission of the X-ray grating versus X-ray energy;

FIG. 19 is a schematic drawing showing a phase-contrast X-ray imaging system;

FIGS. 20a to 20c are X-ray images of a sample showing transmission (absorption), phase, and dark-field (small-angle scattering) information of the sample using the system in FIG. 19; and

FIGS. 21a and 21b are schematic diagrams of micropillars.

### DETAILED DISCLOSURE

The disclosure is directed at a multi-layer, high-aspect ratio X-ray grating apparatus and method of fabrication. In one embodiment, the disclosure may include a self-alignment methodology, or process, combined with a multiple layer structure fabrication that provides an improvement over current solutions.

In another embodiment, the disclosure may be seen as a novel method of fabrication of a high-aspect ratio (HAR) grating apparatus that is based on a combination of SU-8 photoresist and LIGA (lithographie, Galvanoformung and Abformung) processes combined with ultraviolet (UV) lithography. In one embodiment, the SU-8 photoresist process can be used to break down a HAR design into multiple lower aspect-ratio designs where they may be stacked to make a HAR structure. Use of multilayers of SU-8 with the same pattern to form a final HAR grating apparatus is novel over current solutions.

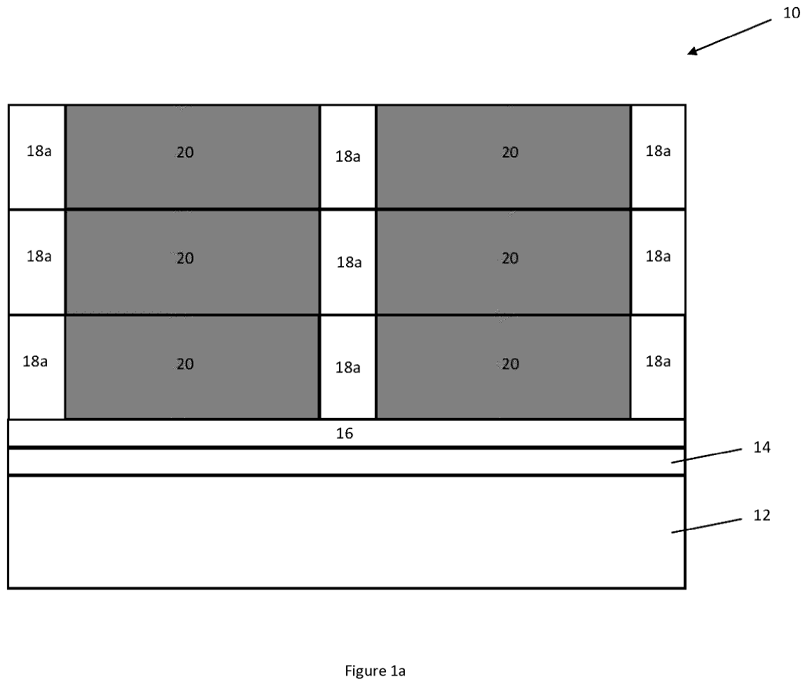

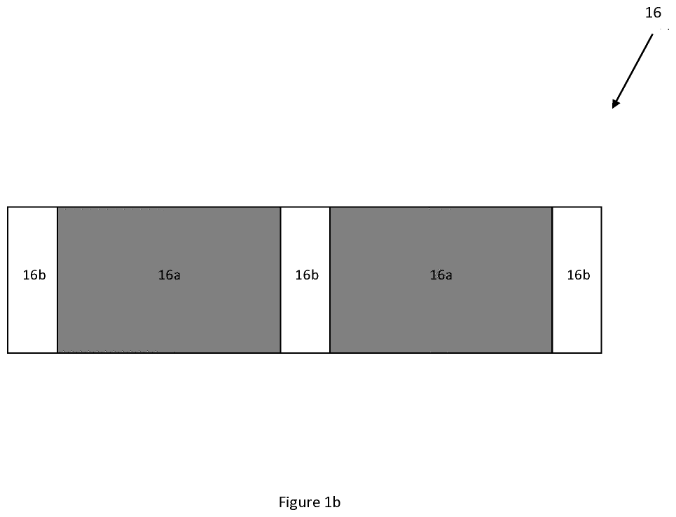

Turning to FIG. 1a, a schematic diagram of a multi-layer, high-aspect ratio X-ray grating apparatus is shown. The apparatus 10 includes a substrate portion 12 and a conductive film layer 14 that is placed on top of the substrate portion 12. In one embodiment, the substrate portion 12 is a UV transparent substrate (including but not limited to glass substrates, flexible films, polymer layers, or plastic sheets) and the conductive film layer 14 is a UV transparent conductive film. In another embodiment, the substrate may be a substrate where there is no need for a conductive film layer. The grating apparatus 10 further includes a seed layer 16, such as a metallic seed layer, which in one embodiment may be a patterned chromium/gold/chromium layer. Atop the seed layer 16 is a photoresist layer 18 (such as, but not limited to, a SU-8 photoresist layer) that is in the form of a set of periodic or non-periodic non-X-ray absorbing structures 18a. Other materials that may be used for the photoresist layer include, but not limited to negative photoresists (such as SU-8, nLOF, KMPR, epoxy-based polymers), positive photoresists (such as AZ and PMMA), epoxy-based polymers, polymers, and photosensitive materials. The photoresist layer, or non-X-ray absorbing layer may be patterned to include gaps between the non-X-ray absorbing structures 18a.

In the current embodiment, the non-X-ray absorbing structures may be seen as pillars or micropillars. In another embodiment, the non-X-ray absorbing structures may be lines. Between the non-X-ray absorbing structures 18a is a set of absorption components 20 which may be formed, in one embodiment, by electroplating, such as, but not limited to, gold electroplating. A height of the non-X-ray absorbing structures 18a and the set of absorption components 20 may be determined based on the application for which the grating apparatus 10 is being used. In some embodiments, multiple photoresist layers 18 and sets of absorption components 20 may be applied (such as three as shown in FIG. 1a). It is understood that the three layers shown in FIG. 1a is one embodiment and that the number of layers may be selected based on a desired height. In some embodiments, the non-X-ray absorbing layer or structures may be integrated with the set of absorption components.

In one embodiment, the photoresist layer is defined (such as to create gaps between the non-X-ray absorbing structures) and then developed, or patterned, via a backside UV exposure methodology which is an improvement over current grating apparatus fabrication methods. This may be seen as part of the self-alignment process as will be described below.

Turning to FIG. 1b, a schematic diagram of one embodiment of the seed layer 16 is shown. In one embodiment, the seed layer 16 includes a first section 16a which may be at least one an opaque and/or conductive section 16a for enabling at least one or both of backside lithography or electroplating. Adjacent the opaque and/or conductive sections 16a are second sections 16b which may be a spatial void or may be filled with a radiation transparent material such as, but not limited to, a non-X-ray-absorbing material. This non-X-ray absorbing material may be the same as the material used for the photoresist layer.

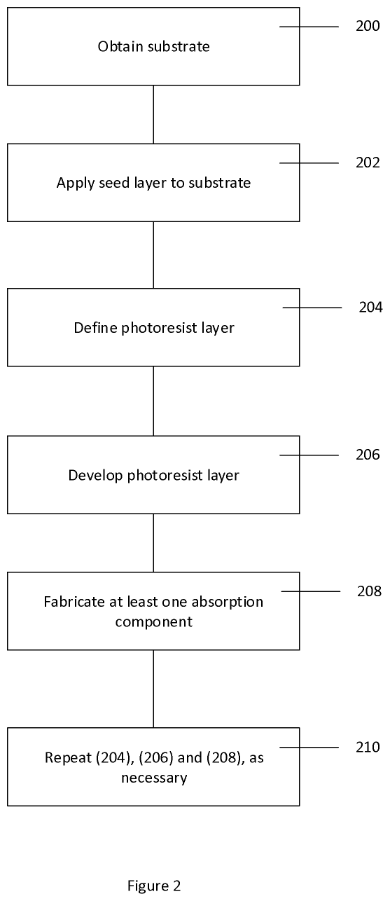

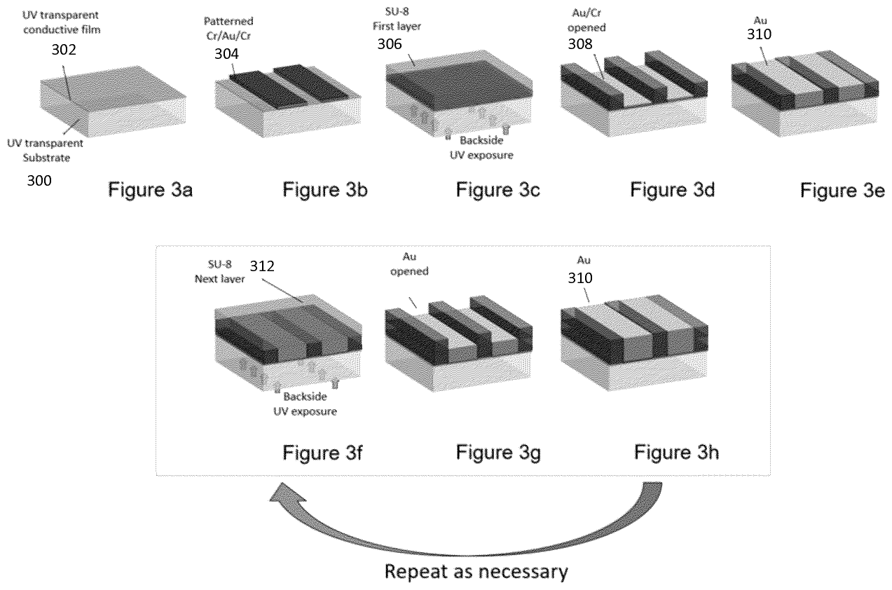

Turning to FIG. 2, a flowchart outlining a method of fabricating a multi-layer, high-aspect ratio X-ray grating is shown. FIGS. 3a to 3h provide a set of schematic drawings showing how the grating may appear at different stages of the fabrication for a self-aligning, multi-layer embodiment.

Initially, a substrate is obtained (200). In one embodiment, such as a multi-layer grating apparatus embodiment, the substrate may be, but not limited to, a glass substrate, a silicon wafer, a flexible film, a polymer layer or a plastic sheet. In another embodiment, such as for a self-aligned multi-layer grating apparatus, the substrate may be an ultraviolet (UV) transparent substrate 300 with a UV transparent conductive film 302 such as schematically shown in FIG. 3a. In some embodiments, the method may include applying the UV transparent conductive film to the UV transparent substrate and, in other embodiments, the UV transparent substrate may already have the conductive film applied.

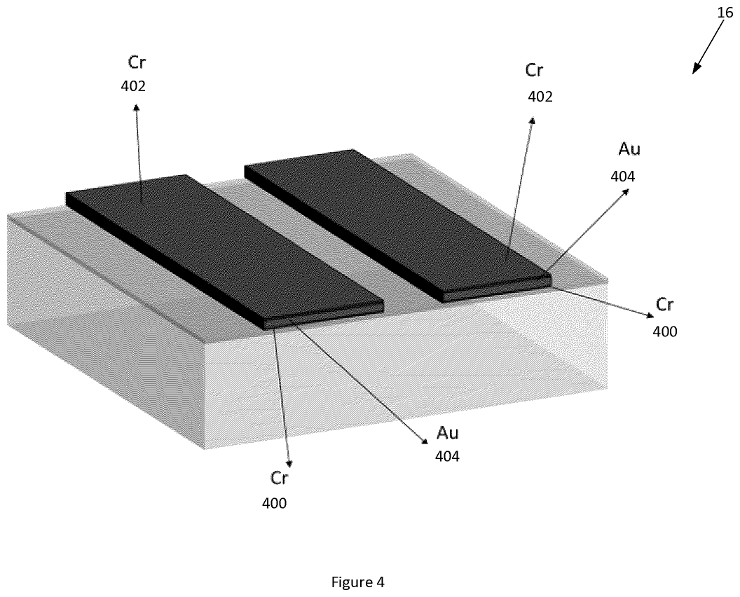

A seed layer, which may be a continuous film, a patterned film, or a patterned film layer, is then applied on top of the substrate (202). In some embodiments, the seed layer may be a metallic seed layer. Application of a seed layer 304 on the UV conductive layer 302 is schematically shown in FIG. 3b. In other embodiments, the method of fabrication may commence with the application of the seed layer film. In one embodiment, the metallic seed layer film is a chromium/gold/chromium film layer. An example of how the seed layer may appear is schematically shown in FIG. 4.

As seen in FIG. 4, the seed layer 16 is patterned such that there are gaps between different sections of the seed layer 16. The seed layer 16 includes first 400 and second 402 layers of chromium sandwiching a layer of gold 404. In some embodiments, the patterning of the seed layer 16 is the opposite pattern of the non-X-ray absorbing structures and the X-ray absorbing components.

A photoresist layer, such as, but not limited to, an SU-8 layer, is then defined (204) and developed or patterned (206) on the seed layer. Other materials for the photoresist layer may be contemplated. The definition and patterning of the photoresist layer may result in a set of non-X-ray absorbing structures (such as pillars 18a of FIG. 1a) and gaps 308 between the non-X-ray absorbing structures. In one embodiment, the photoresist layer 306 is developed or patterned via a backside UV exposure methodology. This is schematically shown in FIGS. 3c and 3d. Electroplating, or other methods including, but not limited to, electrodeposition, centrifugal filling, casting, physical vapour deposition, chemical vapour deposition, plasma enhanced deposition, is then performed or conducted to form at least one absorption component 308 or a set of absorption components (208) within the gaps that were created during the patterning of (206). This is schematically shown in FIG. 3e. In one embodiment, the electroplating may be gold electroplating. The electroplating may fill in the spaces between the defined non-X-ray absorbing structures of the photoresist layer to provide a flat surface.

Depending on a desired height of the photoresist layer and the set of absorption components, (204), (206) and (208) may be repeated as necessary (seen as 210) to meet a desired number of layers or desired thickness or height. This is schematically shown in FIGS. 3f to 3h. As will be understood, a desired thickness of the grating relates to or is associated with an aspect ratio of the grating.

In other words, if necessary, a further photoresist layer 312, such as a further SU-8 layer is then defined (204) and patterned (206) atop the previously developed photoresist layer and set of absorption components. It is understood that the size (or width) of the further photoresist layers (or non-X-ray absorbing structures) and further set of absorption components match the outline or positioning of the previously fabricated grating components. The further layer of photoresist SU-8 may also be produced via a backside UV exposure methodology. In one embodiment, the further layer of photoresist or the SU-8 layer may be produced via a front-side alignment and lithography process. Further electroplating (or filling methods) may then be performed to form absorption components 310 for the further photoresist layer or layer of SU-8 (208).

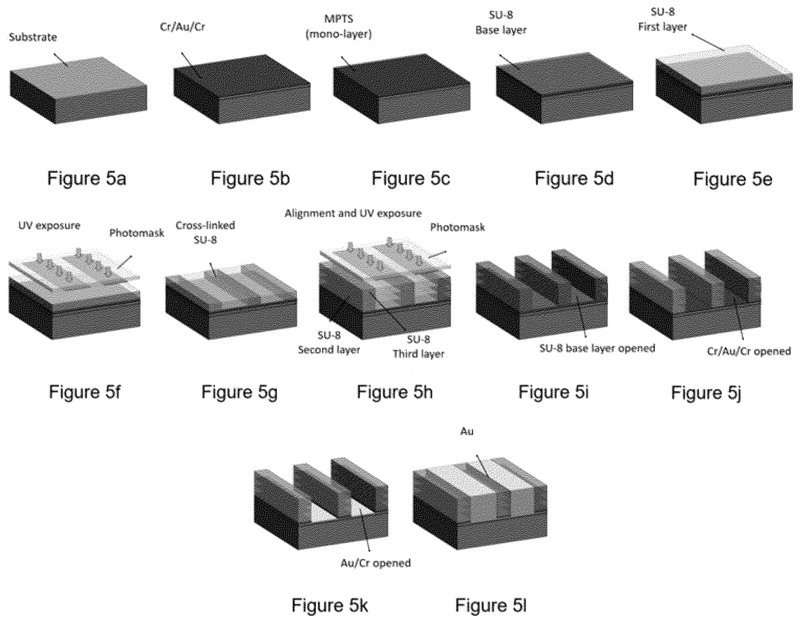

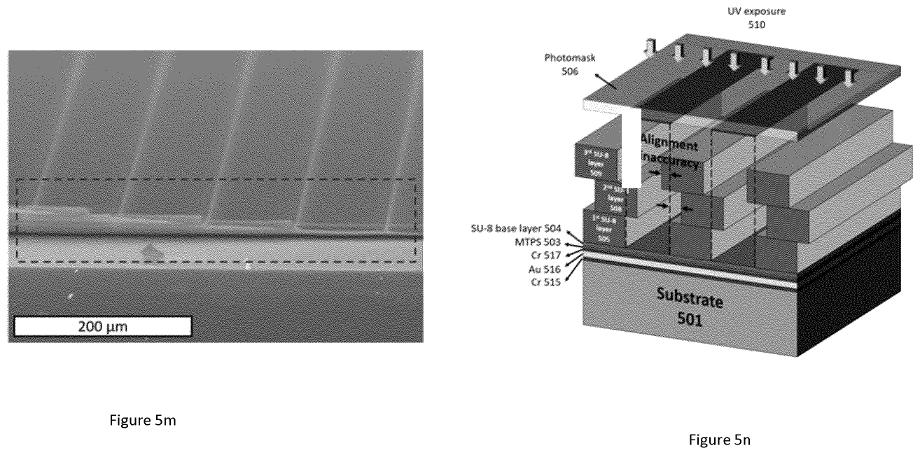

In one specific embodiment of the disclosure, with respect to multi-layer absorption grating design and/or fabrication, experiments were performed to investigate use of a SU-8 based multi-layer design to extend the limit of X-ray grating fabrication. FIGS. 5a to 5l show provide a set of schematic drawings showing how the grating may appear at different stages of the fabrication process for multi-layer HAR gratings.

In this specific embodiment, a substrate such as, but not limited to, a silicon wafer, was cleaned through standard RCA-1 and RCA-2 cleaning processes. This is schematically shown in FIG. 5a.

After obtaining the substrate, the fabrication process began or continued with the definition of a seed layer which, in the current embodiment includes chromium (Cr) and gold (Au) layers. This is schematically shown in FIG. 5b. In the current embodiment, the Cr/Au/Cr films were deposited on the substrate through a thermal evaporation process. In other embodiments, the Cr/Au/Cr seed layer may be deposited through at least one of thermal evaporation, e-beam evaporation, plasma enhanced deposition, or sputtering. In the current embodiment, the thermal evaporation process was performed at room temperature without breaking the vacuum where the thickness of each chromium layer was about 5 nm and the gold film was about 100 nm thick. The bottom chromium layer (in contact with the substrate) acts as an adhesion layer between the gold film of the seed layer and the substrate in the current embodiment.

Typically, adhesion of an SU-8 layer (which may be seen as a photoresist layer), to a gold thin film is not strong which causes the structural integrity of SU-8 molds to be compromised unless at least one adhesion layer is employed. Delamination typically occurs in the developing or electroplating step due to the high internal stress level in SU-8 film. An example of a delaminated SU-8 film from the substrate is illustrated in FIG. 5m. In order to improve the adhesion between the SU-8 and the gold thin film, in the current embodiment, a combination of a thin film of chromium, a mono-layer of 3-(Trimethoxysilyl) propyl methacrylate or MTPS, and a thin layer of SU-8 was used. This is schematically shown in FIG. 5c

The Cr/MPTS combination improves the adhesion of SU-8 to gold thin film, however, it is novel to add another thin layer of SU-8 which further improves the adhesion of subsequent, or further, SU-8 layers to the substrate. The top chromium thin film on the gold also protects the gold film from contaminating the reactive ion etching (RIE) chamber during the etching process and keeps the gold film intact for electroplating. This will be described in more detail below.

In one embodiment, the mono-layer MPTS on chromium thin film was formed through a liquid treatment step using ethanol and acetic acid prior to the definition (or deposition) of a thin layer of SU-8 or the photoresist layer.

A layer of SU-8 was then defined (FIG. 5d). In one embodiment, the SU-8 layer may be developed by spin coating. In another embodiment, the thin layer of SU-8 may be produced, or fabricated, by diluting SU-8 2015 with Cyclopentanone to achieve a desired thickness for the SU-8 layer (which may be seen as SU-8 base layer).

After the SU-8 base layer was spin coated, the apparatus was subjected to a soft baking step. In the current embodiment, the soft baking was performed at about 65° C. for about 60 minutes through a ramping up (from room temperature) and ramping down (to room temperature) process with a rate of 120° C. per hour. Ramping the temperature during the soft bake, post-exposure bake, and hard bake was found to be necessary to minimize or reduce the high-stress level associated with the SU-8 polymerization process. The SU-8 base layer was then flood exposed in i-line, and a post-exposure bake was performed at about 65° C. for about 60 minutes with the same condition as the soft bake. A hard bake step was performed for about 30 minutes at about 170° C. with the same ramping condition as the soft bake to further improve the mechanical stability of the SU-8 base layer during fabrication.

Experimental results showed that the combination of a thin layer of chromium, a mono-layer of MPTS, and a thin layer of hard-baked SU-8 reduced the likelihood that the subsequent (or further), possibly thicker, SU-8 layers would delaminate, peel off, or break during the fabrication process.

In another embodiment of fabrication, a first SU-8 layer was spin-coated (FIG. 5e), followed by a soft bake step. A thickness of the first SU-8 layer was selected, or predetermined, based on a smallest feature size on the photomask such that the aspect ratio of molds did not exceed a height to width ratio equal to 5 to provide for a sidewall quality in the patterned structures in the SU-8 layer.

After performing UV-lithography (FIG. 5f) through a hard-contact mode and conducting a post-exposure bake (FIG. 5g), subsequent layers of SU-8 could then be added to increase a thickness of the overall SU-8 layer (FIG. 5h). In one embodiment, this can be can be achieved by repeating the process schematically shown in FIG. 5e to FIG. 5g. In another embodiment, the subsequent, or further, layers of SU-8 were spin coated, soft baked, aligned with the photomask, and exposed by UV light through a hard-contact mode in the same manner until the desired total thickness of structures was achieved or fabricated. The uncrosslinked parts of SU-8 resist were then developed (FIG. 5i) in one of, but not limited to, propylene glycol methyl ether acetate (PGMEA) or 1-Methoxy-2-Propanol Acetate or acetone followed by a hard bake step to ensure the mechanical stability of the final structure (FIG. 5i).

Before forming the absorption part, or components, of the grating, portions of the SU-8 base layer were removed through an RIE dry etching process (FIG. 5j) such as by using a combination of O₂ and CF₄ gases until the top chromium thin film was reached. This may also be seen as patterning the photoresist layer.

This chromium thin film, as stated earlier, not only improves the adhesion of the SU-8 structural layer to the gold film, but also protects the gold film from being attacked, or affected, by the etching gases and exposure to the RIE chamber.

The chromium thin film was then removed through a wet process at room temperature using a chromium etchant or dry etching process (FIG. 5k). In one embodiment, the chromium etchant may be made from ceric ammonium nitrate ((NH4)2[Ce(NO3)6]), acetic acid (CH3COOH), and deionized (DI) water. The sample was then ready for forming the absorption parts of the grating between the SU-8 non-X-ray-absorption structures or parts through a process such as metal (Au) electroplating (FIG. 5l).

In this embodiment, the multi-layer HAR X-ray grating fabrication process utilizes a multi-layer design which benefits from breaking a final high aspect ratio structure down into multiple lower aspect ratio ones. It was determined by the inventors that it is novel to achieve or fabricate a high-aspect ratio grating structure through a multi-layer design.

Through experiments, various feature sizes of SU-8 structures were fabricated to investigate the practicality of this grating fabrication method in X-ray absorption fabrication using standard UV-lithography tools.

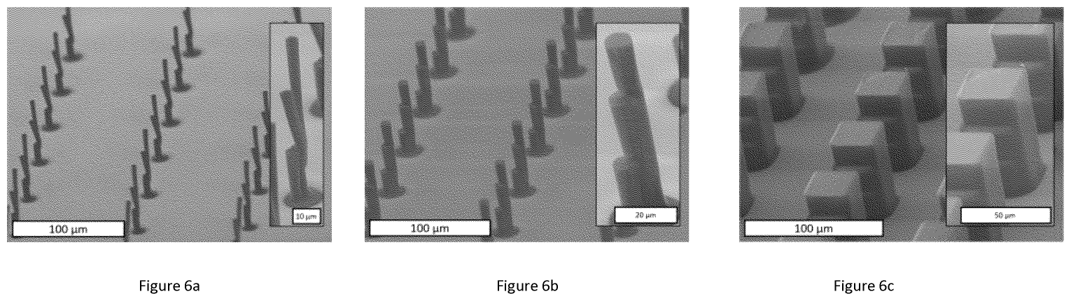

The experimental results showed that alignment accuracy during each exposure step plays a critical role in the final structure integrity, as schematically depicted in FIG. 5n. FIGS. 6a to 6c are scanning electron microscopy (SEM) images of a fabricated multi-layer (three-layer) SU-8 structure for three different feature sizes. Although alignment inaccuracy may be a bottleneck for fabricating high-resolution structures (FIG. 6a), a multi-layer design can be effectively employed where alignment inaccuracy is comparably smaller than the minimum or a small feature size of the design (FIG. 6c).

For high-resolution structures, the disclosure is directed at a novel fabrication process which eliminates or reduces the alignment step through a self-aligned technique.

With respect to the multi-layer embodiment disclosed above, while it enables the X-ray grating fabrication to extend the grating's aspect-ratio, high-resolution and micro-scale structures are typically not possible due to alignment inaccuracy issues. Therefore, in another embodiment of a multi-layer structure fabrication process, regardless of the structure feature size, the fabrication process includes a self-alignment aspect or process.

This self-alignment aspect uses a self-aligned lithography technique to define new fabrication processes and devices, particularly for X-ray absorption grating fabrication, which was not previously possible. The self-aligned process is based on a backside exposure method rather than a front side exposure as is currently employed.

Given the structure of an X-ray grating, two main challenges are addressed in order to allow a self-aligned design for X-ray absorption grating to be feasible. For this embodiment, silicon wafers cannot be employed as a substrate since a self-aligned design requires a UV transparent substrate, such as, but not limited to, glass substrates, flexible films, polymer layers or plastic sheets.

As previously discussed with respect to FIG. 5b, a continuous gold film is used as a seed layer for the electroplating step. This continuous gold film (based on thickness) blocks any backside UV exposure from reaching the SU-8 layer. Moreover, as shown in FIG. 5k, not all of the gold film is used during the electroplating, and only the parts that are not covered by non-X-ray absorbing SU-8 layer act as a seed layer for electroplating. As a result, the seed layer is patterned such that only the absorption components of the X-ray grating have a seed layer. This patterned gold film is also used as a self-aligned mask for UV backside lithography or backside exposure. In some embodiments, depending on the grating design, the patterned gold film could result in discrete areas that should be electrically connected for the electroplating process. In order to address this, a radiation (UV) transparent conductive layer is introduced prior to the introduction of the patterned Cr/Au/Cr layer (seed layer) to ensure or enable an electrical connection between the discrete areas of the electroplating seed layer. In one embodiment, the radiation transparent film may be one of, but not limited to, ITO, AZO, Au, Si and the like.

FIGS. 7a to 7n provide schematic diagrams of the fabrication process for one embodiment of a self-aligned multi-layer grating fabrication.

Initially, a glass substrate with an ITO layer applied to the substrate is obtained. This is schematically shown in FIG. 7a. A seed layer (such as a Cr/Au/Cr film) was then patterned on the ITO-on-glass substrate through selectively wet etching the Cr/Au/Cr film. This is schematically shown in FIGS. 7b to 7e. In another embodiment, the patterned Cr/Au/Cr film may be produced using other techniques such as a liftoff process as schematically illustrated in FIGS. 7o to 7q.

A mono-layer of MPTS (which may be seen as an extra adhesion layer) was then applied (FIG. 7f) through a liquid treatment step to enable the adhesion between the ITO layer and chromium to the next SU-8 base layer. In some embodiments, there may not be a need for the extra adhesion layer. Other materials such as OmniCoat or HMDS may be used for the extra adhesion layer. A 500 nm thin film of SU-8 was then spin coated (FIG. 7g), UV exposed from the top in flood exposure mode and hard baked to serve as a base layer for subsequent thick SU-8 layers. In this experiment, all baking steps for SU-8 layers were performed according to the process discussed above with respect to FIG. 5. The first coated non-X-ray-absorbing SU-8 layer then underwent a backside UV exposure (FIG. 7h). In the current embodiment, this was performed through a flood exposure from the backside of the sample where the patterned Cr/Au/Cr layer acted as a photomask right underneath the first SU-8 layer. A gap of about 400 nm was experienced between the self-aligned photomask (patterned Cr/Au/Cr) and the first SU-8 layer due to the presence of the 500 nm thin SU-8 base layer. After developing the first SU-8 layer (FIG. 7i), the sample was hard-baked to ensure the SU-8 mechanical stability during the following fabrication process. The 500 nm SU-8 base layer was then dry etched (FIG. 7j) such as via a RIE process followed by a wet etching process to remove the top chromium thin film. At this point, the gold film was open for electroplating (FIG. 7k) to form the first layer of absorption parts or absorption components.

After conducting the electroplating and filling the gaps between the SU-8 molds completely, the second non-X-ray absorbing SU-8 layer was coated. This is where the first layer absorption parts (electroplated regions) acted as a self-aligned photomask for the subsequent non-X-ray absorbing SU-8 layer during backside UV exposure and transferred the same pattern onto the next non-X-ray absorbing SU-8 layer. It was expected, and confirmed, that the patterns would be transferred without any misalignment since there is no need for an alignment step, and there is no gap between the self-aligned photomask and the next non-X-ray absorbing SU-8 layer. This fabrication process provides a quality side-wall in SU-8 lithography and can be repeated as many times as required until the desired thickness of an absorption grating is achieved.

This method of X-ray grating fabrication benefits from both self-aligned lithography (which eliminates, or reduces, the alignment inaccuracy) and a multi-layer design through UV lithography (which increases the aspect ratio of any structure) without any limitation on the mechanical stability of the fabricated X-ray gratings. In other embodiments, the self-aligned multi-layer fabrication method may also be compatible with X-ray lithography. Also, the self-aligned multi-layer fabrication method may be employed in the X-ray LIGA process to further extend the grating's aspect ratio.

An optimal exposure dose was selected based on the pattern transfer quality, feature sizes, periodicity of features, and SU-8 thickness at the dose that SU-8 features become sufficiently cross-linked with an acceptable sidewall quality. FIGS. 7r and 7s are SEM images of backside UV exposure in creating periodic line features over a large area. FIGS. 8a to 8c show the effect of various amounts of exposure doses on the pattern transfer quality.

With respect to the effect of feature size (such as a width of the non-X-ray absorbing structures), experiments were performed to fabricate various feature sizes of non-X-ray absorbing SU-8 structures in the form of periodic lines and/or micropillars to evaluate the quality of non-X-ray absorbing SU-8 structures. A thickness of coated non-X-ray absorbing SU-8 was selected to be around 10 μm such that the aspect ratio of features did not exceed 10, as there were multiple feature sizes (from 1 μm to 5 μm) on the same die.

Patterns were created simultaneously through the self-aligned backside UV exposure. Successful fabrication for feature sizes as small as 1 μm thick was obtained as shown in FIGS. 12a to 12j. These figures illustrate features with 1 μm thickness (FIGS. 12a and 12f) to 5 μm thickness (FIGS. 12e and 12j). The periodicity of all these structures was kept equal, which in the current embodiment was 10.8 μm, to match the grating with the detector pixel size of the X-ray imaging setup of this embodiment. Use of the self-aligned backside UV exposure is innovative with respect to the fabrication of micrometre scale gratings for high-resolution systems. With higher aspect ratio structures in a single non-X-ray absorbing SU-8 layer, the quality of lithography in sub-micron scale feature size structures degrades, a limitation associated with the wavelength of standard UV light sources.

With respect to electroplating, in experimentation, a metal electroplating step was conducted or performed for each aspect of the self-aligned multi-layer fabrication process to form the absorption components for the X-ray gratings of the disclosure. These electroplated parts also served as a lithography mask for use in the backside UV exposure for subsequent non-X-ray absorbing SU-8 layers. A successful pattern transfer in the self-aligned backside UV exposure was required for quality electroplating. Multiple samples were tested by conducting gold (Au) and indium (In) electroplating. Gold is the most common metal utilized for X-ray grating fabrication, as it possesses a heavy atomic number which can effectively absorb X-ray photons. While gold electroplating was used in one embodiment of fabrication, other materials such as, but not limited to, platinum, nickel, lead, selenium, bismuth, tungsten or indium may also be used.

In one embodiment, electroplating of gold was conducted using a sodium gold sulfite solution with 8.2 g/L concentration and a slightly acidic pH (6.3). The electroplating solution was warmed up and kept at around 49° C. (121° F.) using a PLC-controlled electric immersion heater, and the solution was filtered and stirred throughout the process to create an electroplating uniformity across the sample. A platinized titanium mesh anode with a surface area greater than the X-ray grating was used for electroplating, which was kept 10 cm away from the grating. Electroplating was performed at the nominal current density of 3 mA/cm2 using a constant current source, resulting in a growth rate of around 100 nm/min. The gratings were cleaned and washed using de-ionized (DI) water both before immersion into the electroplating solution and after the electroplating was completed. The samples were then dried with nitrogen (N₂) after being rinsed at the end of electroplating.

Quality electroplating for successful self-aligned lithography required samples not to be overplated as this results in the UV transparent regions being covered, which eventually changes the shape of the structure in subsequent layers. In order to avoid such adverse behaviour, samples with overplated gold were partially wet etched. The gold etchant was diluted in DI water (1:2 vol/vol) to provide improved control over the etching rate. FIGS. 13a to 13e illustrate SEM images of a SU-8 line buried under overplated gold (FIG. 13a), which had been undergone a partially gold wet etching process (FIG. 13c) until the excessive gold plated regions were removed, and the SU-8 line was released (FIG. 13d). FIGS. 13a and 13e are SEM images taken at an angle to provide a view of overplated gold and when it is etched.

For indium electroplating, commercially available In Sulfamate Plating Bath 3N was used for indium electroplating. This solution is acidic with a pH of between about 1.5-2.0. The pH was monitored for each test and adjusted to maintain the pH by titrating a 10% sulfamic acid in DI water (1:9 wt/wt) solution into the indium solution. An indium anode with a surface area greater than the size of samples was placed 6.5 cm away from samples, all in a large beaker, while the solution was being physically stirred using a magnetic stir bar with a speed of 340 RPM. Samples were rinsed with DI water and immersed first in the 10% sulfamic acid to ensure having an acidic base metallization surface and preparing samples for the next step electroplating in indium sulfamate plating bath. Electroplating was then conducted at room temperature utilizing a constant current source with a current density of 16 mA/cm2, resulting in a growth rate of around 700 nm/min. The samples were rinsed with DI water after the completion of indium plating and then dried with N₂. Indium etching could not be performed using indium etchant (which is diluted hydrochloric acid solution in DI water) on overplated indium samples due to the presence of ITO on the sample, in one embodiment that uses ITO as the radiation transparent conductive film on the substrate. ITO contains indium which would get etched and results in SU-8 features being peeled off the substrate. Therefore, intermittent indium plating was used until features were slightly underplated to have better control over pattern transfer in self-align lithography. FIGS. 14a to 14e are SEM images of samples electroplated by—where we performed intermittent electroplating—to observe the plating quality. FIG. 14b is an example of sufficiently indium electroplated sample, with a closer view at SU-8 features in FIG. 14d. An SEM image of an overplated indium sample is also illustrated in FIG. 14c, where SU-8 is partially covered with overplated indium.

With respect to multi-layer backside UV lithography, after successfully electroplating and forming the absorption components, samples were rinsed with DI water, dried with N₂, and the subsequent SU-8 layer was coated to produce a second layer of structures. The second SU-8 layer thickness, similar to the first SU-8 layer, was selected based on the smallest feature size (width of non-X-ray absorbing structures) such that the resulting self-aligned backside UV exposure pattern transfer—with the highest possible aspect ratio and an acceptable sidewall angle—was complete. The self-aligned backside UV exposure was performed using a higher exposure energy to compensate for the energy loss at the first SU-8 layer. After developing samples in SU-8 developer, a hard bake step was also carried out to enhance structures mechanical stability. SEM images of various feature sizes of the second SU-8 layer are illustrated in FIGS. 9a to 9d. The quality of the second SU-8 layer backside UV exposure on samples electroplated with indium and gold was investigated. In FIGS. 9a and 9b micropillars in the first SU-8 layer were sufficiently electroplated using indium plating. In FIGS. 9c and 9d, on the other hand, structures in the first SU-8 layer were slightly underplated with gold. Micropillars with a diameter as small as 1.5 μm with an aspect ratio of 10 with two layers of SU-8 (FIG. 9d) were successfully fabricated.

Increasing the number of layers also resulted in gratings with a higher aspect ratio. FIGS. 10a to 10c are SEM images of micropillars before (FIG. 10a) and after (FIG. 10b) creating the second SU-8 layer through the self-aligned backside UV exposure. While the micropillars in FIG. 10a were underplated with indium, they resulted in an acceptable pattern transfer from the first SU-8 layer. The same scenario with an underplated first SU-8 layer with indium was tested on line gratings, where a complete pattern transfer of structures was achieved through the self-aligned backside UV exposure technique. FIG. 10c depicts an SEM image of a line grating with two non-X-ray absorbing SU-8 layers (the image was taken before unexposed regions of the second SU-8 layer were developed entirely).

FIGS. 11a and 11b show a sample with two non-X-ray absorbing SU-8 layers before (FIG. 11a) and after (FIG. 11b) electroplating the second non-X-ray absorbing SU-8 layer with indium. The self-aligned multi-layer fabrication process of the disclosure for X-ray grating can be repeated for as many layers as required until a desired thickness of the absorber material is achieved.

With respect to large-area grating fabrication, by experimenting with the self-aligned multi-layer fabrication process on smaller test samples, various larger sizes of gratings on glass substrates were able to be fabricated.

Micropillar-based gratings with 4 μm aperture size and 16.2 μm period were fabricated in three different sized devices, namely 20 mm×20 mm, 40 mm×40 mm, and 70 mm×70 mm. The 20 mm×20 mm devices were used as test samples. 4-inch glass substrates with 700 μm thickness were used as the substrate.

FIGS. 15a to 15c show three fabricated gratings with 20 mm×20 mm designs in FIG. 15a, 40 mm×40 mm designs in FIG. 15b, and 70 mm×70 mm designs in FIG. 15c, all mounted on an aluminum holder for easier handling. Although taking SEM images is the proper method to inspect the quality of electroplating for each layer, an innovative method was created for grating investigation, which helped expedite the process and reduced the number of times needed to take SEM images of a large area grating. In one embodiment of this novel grating investigation or testing a quality of a fabricated X-ray grating, a pointer laser (such as a 630 nm (red) laser source), is used to illuminate the gratings. In another embodiment, light sources at visible wavelengths such as, but not limited to, white LED lights or flash lights may be used. This is schematically illustrated in FIG. 16a. The testing apparatus 1600 includes a light source 1602, such as a pointer laser source, and a screen 1604. The X-ray grating being tested 1606 is placed between the laser source 1602 and the screen 1604. Since the X-ray grating includes a transparent substrate, by illuminating the grating with the pointer laser source 1602, a Fourier transform pattern of grating designs could be observed on the screen 1604 providing visually sufficient information to determine a quality of the electroplated structures within the X-ray grating 1606. If the structures were overplated, the Fourier transform on the screen 1604 would appear distorted or deformed or have an obvious change in shape from their original pattern.

FIG. 16b illustrates another embodiment of a setup used for the quality test of electroplating with a laser source, and the test setup with two examples of the Fourier transform pattern of gratings with line 1608 as well as micropillar structures 1610. Referring back to FIG. 16a, the laser source to the grating distance (Z1) and the grating to the screen (Z2) distance were selected to have better visualizations of the pattern on the screen 1604. These numbers were selected to distinguish between the Fourier transform patterns of gratings based on the specifications, such as but not limited to wavelength, of the laser or light source 1602 and specifications, such as but not limited to periodicity and feature size, of the grating 1606.

Turning to FIG. 16c, a flowchart showing a method of testing a quality of a fabricated X-ray grating is shown. Initially, a fabricated X-ray grating is obtained (1620). In one embodiment, the X-ray grating has a radiation transparent substrate. The X-ray grating is then placed between a light source and a screen. A distance between the light source and the grating may be represented by Z1 of FIG. 16a and a distance between the X-ray grating and the screen may be represented by Z2 of FIG. 16a.

Selection of Z1 and Z2 may be based on the specifications, such as, but not limited to, wavelength, of the laser or light source 1602 and/or specifications, such as, but not limited to, periodicity and feature size, of the grating 1606 and/or to improve visualization of a pattern.

The X-ray grating is then illuminated by the light source (1620). As the X-ray grating is directly between the light source and the screen, images of the grating or images of the characteristics of the grating are generated on the screen. These images may be in the form of Fourier transform patterns. The images (such as the Fourier transform patterns) are then observed (1624). Observation of these images for deformations or changes in the expected Fourier transform patterns enables the viewer to determine a quality of the X-ray grating being tested.

While SEM and laser source projection techniques provide a good impression of the quality of fabrication in each step, X-ray projection of fabricated gratings can reveal the ultimate quality of a final device. X-ray projection provides in-depth information about the transmission characteristics of the absorption grating. A three-layer micropillar-based grating with 4 μm aperture size and 16.2 μm period size was inspected. The thickness of this grating—electroplated with gold—was around 40 μ/m. An X-ray image (FIG. 17b) of a fabricated grating was taken using the system illustrated in FIG. 17a.

As shown in FIG. 17a, the system 1700 includes an X-ray source 1702 that is directed at a high-resolution X-ray detector 1704. The X-ray grating 1706 of interest is placed between the X-ray source 1702 and the X-ray detector 1704. When the grating is illuminated, an X-ray image 1708 is generated by the X-ray detector 1704.

In one embodiment, a source to grating distance (Z1) of 10 cm, and grating to detector distance (Z2) of 35 cm were used. In this embodiment, these distances were selected to generate a magnified image of speckles on the detector so that their profiles could be more easily resolved. A closer view of the speckles profile and cross-sectional graphs of their normalized transmission profile are shown in FIGS. 17c and 17d. The visibility map of the grating is also illustrated in FIG. 18a. The visibility, transmission, and absorption characteristics versus various X-ray source potentials were investigated with respect to the X-ray grating. These are shown in FIGS. 18b and 18c. Higher visibilities were achievable by increasing the number of layers in the proposed fabrication process, potentially creating higher contrast between the absorbed and transmitted X-ray patterns on the X-ray projection.

In one embodiment, an X-ray grating in accordance with the disclosure may be integrated within an X-ray phase contrast imaging system. This is schematically illustrated in FIG. 19. The X-ray phase contrast imaging system 1900 includes an X-ray source 1902, an X-ray absorption grating (pre-sample mask) 1904 and an X-ray detector 1906. An object of interest 1908 is placed between the X-ray grating 1904 and the X-ray detector 1906. In other embodiments, two or more X-ray absorption gratings 1904 may be used to realize other X-ray imaging systems.

In this embodiment the distance (Z1) (or the source to object distance) between X-ray source 1902 and the object 1908 and the distance (Z2) (or the object to detector distance) between the object 1908 and the detector 1906 are selected based on the X-ray absorption grating, detector, and source specifications. In another embodiment, three different images, transmission (absorption), phase, and small angle scattering (dark-field) may be produced using a single-exposure X-ray. The innovation is with the system compactness, resolution of image using an X-ray absorption grating of the disclosure, and multi-directional sensitivity of X-ray on retrieved images. The registered data from the detector was processed afterward to produce the three aforementioned images. Example images are shown as a transmission (absorption) image in FIG. 20a, a phase image in FIG. 20b, and a small-angle scattering (dark-field) image in FIG. 20c.

In experimentation, the novel method of the disclosure was realized and provides a process for large area high-resolution X-ray absorption grating fabrication. In one embodiment. the method of the disclosure includes a self-aligned multi-layer process that allows employing conventional UV-LIGA to generate high-aspect ratio micron-scale structures to fabricate X-ray gratings. Furthermore, this fabrication process does not require any special or sophisticated processing technologies—such as synchrotron facilities used in X-ray LIGA, or deep reactive ion etching along with atomic layer deposition in silicon-based fabrication processes. By stacking multiple layers of the same grating design (multi-layer structures) through a simple backside UV flood exposure technique (a self-aligned design) and without any alignment steps, not only the proposed process facilitates X-ray absorption grating fabrication at no extra costs, but also it increases the large scale fabrication and development capability. By leveraging thin-film transistor technology, we also demonstrated the feasibility of translating the proposed method into large area X-ray grating fabrication for larger field-of-view imaging applications. The compatibility of this fabrication process with UV-LIGA is an advantage compared to other methods—like X-ray LIGA—as it plays a considerable role in fabricating large area high-resolution gratings with significantly higher throughputs. Moreover, this fabrication process can be employed to further increase the aspect ratio of already fabricated X-ray absorption gratings on silicon, graphite, plastic, polymer, flexible, or glass substrates through X-ray LIGA, for higher energy X-ray imaging applications. X-ray absorption gratings are the building block in grating-based X-ray phase-contrast imaging systems using coded-aperture, edge-illumination, Talbot, Talbot-lau, speckle-based, hartmann sensors, or grating interferometric methods. The X-ray absorption gratings directly determine the imaging quality. This innovation addresses one of the challenging technological bottlenecks in grating-based X-ray phase-contrast imaging systems—the fabrication of large area high-resolution X-ray absorption gratings. This innovation paves the pathway for X-ray absorption grating fabrication that potentially enables X-ray imaging for clinical (and non-clinical) applications where higher visibility (quality), higher energy, higher field-of-view, higher resolution, or compact imaging are of interest.

In another embodiment, the fabrication of the X-ray grating may further include fabrication of a bridge-assisted micropillar structure. By providing auxiliary supporting bridges to micropillar structures (FIG. 21a), such as HAR micropillar structures, within an X-ray grating, the mechanical stability of the micropillars are improved which may result in standing HAR structures (FIG. 21b). Use of these bridge-assisted micropillars may provide for higher sensitivity XPCi systems. In one embodiment, different micropillars (with or without auxiliary supporting bridges) may be fabricated to investigate their mechanical stability.

Although the present disclosure has been illustrated and described herein with reference to various embodiments and specific examples thereof, it will be readily apparent to those of ordinary skill in the art that the elements of the embodiments may be combined in other ways to create further embodiments and also other embodiments and examples may perform similar functions and/or achieve like results. All such equivalent embodiments and examples are within the spirit and scope of the present disclosure as defined by the claims. For example, the principles and concepts herein are believed to apply to other shape memory materials, including shape memory plastics or the like.

In the preceding description, for purposes of explanation, numerous details may be set forth in order to provide a thorough understanding of the embodiments. However, it will be apparent to one skilled in the art that these specific details may not all be required. In other instances, well-known structures may be shown in block diagram form in order not to obscure the understanding. For example, specific details are not provided as to whether elements of the embodiments described herein are implemented as a software routine or computer readable code to be executed by a processor or as a hardware circuit, firmware, or a combination thereof.

What is claimed is:

1. A method of fabricating a multi-layer X-ray grating comprising:
applying a seed layer on a radiation transparent substrate;
fabricating at least one patterned non-X-ray absorbing layer atop the seed layer, the at least one patterned non-X-ray absorbing layer including gaps; and
fabricating at least one X-ray absorbing layer atop the seed layer into the gaps of the at least one non-X-ray absorbing layer.

2. The method of claim 1 wherein fabricating the at least one patterned non-X-ray absorbing layer comprises exposing the grating to backside radiation exposure.

3. The method of claim 1 wherein fabricating the at least one X-ray absorbing layer comprises exposing the grating to backside radiation exposure.

4. The method of claim 2 wherein exposing the grating to backside radiation exposure enables self-alignment of the at least one patterned X-ray absorbing layer.

5. The method of claim 3 wherein exposing the grating to backside radiation exposure enables self-alignment of the at least one X-ray absorbing layer.

6. The method of claim 2 wherein the backside radiation exposure is performed via ultraviolet (UV) exposure, extreme UV (EUV) exposure, deep DUV (DUV) exposure, near infrared (NIR) exposure, infra-red (IR) exposure or X-ray lithography.

7. The method of claim 3 wherein the backside radiation exposure is performed via ultraviolet (UV) exposure, extreme UV (EUV) exposure, deep DUV (DUV) exposure, near infrared (NIR) exposure, infra-red (IR) exposure or X-ray lithography.

8. A multi-layer high-aspect ratio X-ray grating comprising:
a substrate;
a seed layer on top of the substrate;
at least one patterned non-X-ray absorbing layer atop the seed layer, the at least one patterned non-X-ray absorbing layer including gaps; and
at least one X-ray absorbing layer atop the seed layer, the at least one X-ray absorbing layer located within the gaps of the at least one patterned non-X-ray absorbing layer.

9. The X-ray grating of claim 8 wherein the seed layer is at least one of opaque or electrically conductive.

10. The X-ray grating of claim 8 wherein the at least one patterned non-X-ray absorbing layer is a photo-sensitive layer.

11. The X-ray grating of claim 8 wherein the at least one patterned non-X-ray absorbing layer is a layer of negative photoresist, a layer of positive photoresist, a layer of an epoxy-based polymer, a layer of a polymer, or a layer of photosensitive material.

12. The X-ray grating of claim 8 wherein the at least one X-ray absorbing layer is made from gold, platinum, nickel, lead, selenium, bismuth, tungsten, or indium.

13. The X-ray grating of claim 8 further comprising an adhesion layer atop the seed layer.

14. The X-ray grating of claim 13 wherein the adhesion layer is MPTS.

15. A phase contrast imaging system comprising:
an X-ray source;
an X-ray detector; and
at least one multi-layer high-aspect ratio X-ray grating including:
a substrate;
a seed layer on top of the substrate;
at least one patterned non-X-ray absorbing layer atop the seed layer, the at least one patterned non-X-ray absorbing layer including gaps; and
at least one X-ray absorbing layer atop the seed layer, the at least one X-ray absorbing layer located within the gaps of the at least one patterned non-X-ray absorbing layer;
wherein the X-ray grating is located between the X-ray source and the X-ray detector; and
wherein an object of interest is located between the X-ray source and the X-ray detector.

16. The phase contrast system of claim 15 wherein a first distance between the X-ray source and the object of interest and a second distance between the object of interest and the X-ray detector are selected based on X-ray source, X-ray detector and X-ray grating specifications.

17. The phase contrast system of claim 15 wherein the at least one patterned non-X-ray absorbing layer is a photosensitive layer.

18. The phase contrast system of claim 15 wherein the at least one X-ray absorbing layer is made from gold, platinum, nickel, lead, selenium, bismuth, tungsten, or indium.

19. The phase contrast system of claim 15 wherein the high-aspect ratio X-ray grating is fabricated using at least one of a backside exposure process or a self-alignment process.
